(19) United States
(12) Patent Application Publication
(10) Pub. No.: US 2006/0011466 A1
(43) Pub. Date: Jan. 19, 2006

(54) Method of fabricting indium tin oxide film with well thermal stabilization and low resistivity

(75) Inventor: Chien-Chung Chen, Taichung City (TW)

Correspondence Address: BACON & THOMAS, PLLC, 625 SLATERS LANE, FOURTH FLOOR, ALEXANDRIA, VA, 22314, US

(73) Assignee: Wintek Corporation, TAICHUNG (TW)

(21) Appl. No.: 10/923,733

(22) Filed: Aug. 24, 2004

(30) Foreign Application Priority Data
Jul. 19, 2004 (TW) 93121530

(51) Int. Cl. C23C 14/32; C23C 14/00

(52) U.S. Cl. 204/192.11; 204/192.15

(57) ABSTRACT

A method of fabricating an indium tin oxide film (ITO film) with well thermal stabilization and low resistivity has the steps of: a) Provide a silicon dioxide film and a titanium dioxide film on a substrate, wherein the stacked silicon dioxide film and the titanium dioxide form an oxide dielectric layer. b) Provide an ion beam, which is generated by introducing oxygen to an ion source, to a surface of the oxide dielectric layer to take the ion process on the surface of the oxide dielectric layer. c) Provide an indium tin oxide film on the surface of the oxide dielectric layer. The thermal stabilization and the resistivity of the ITO film are kept stable to make the ITO film having a well light transmission.

### BACKGROUND OF THE INVENTION

1. Field of the Invention

The present invention relates generally to an electronic device, and more particularly to a method of fabricating an indium tin oxide (ITO) film, which the film has a well thermal stabilization and a low resistivity.

2. Description of the Related Art

In a touch panel, the indium tin oxide film (ITO film) is the most import element that affects the quality of the product.

In prior art for enhancement of light transmission of the ITO film, the sputtering process is applied to deposit a titanium dioxide film (TiO₂ film), a silicon dioxide film (SiO₂ film) and the ITO film on a plastic substrate in sequence. The TiO₂ film and the SiO₂ film form an oxide dielectric layer for anti-reflection. The ITO film has a high refractive index and the SiO₂ film has a low refractive index, which the difference of phases of reflected light of the ITO film and the SiO₂ film causes destructive interference. As a result, the light transmission the ITO film is increased.

In the process of fabrication of the panel, such as annealing, curing and reliability, heat will cause oxygen in the dielectric oxides diffusing into the ITO film that changes the surface resistance of the ITO film, such as the thermal stabilization is decreased and the resistivity is increase, and that makes the ITO film having a poor quality.

### SUMMARY OF THE INVENTION

The primary objective of the present invention is to provide a method of fabricating an ITO film, which processes the oxide dielectric layer with oxygen ion beam to fill the empty portion thereof. Therefore, the ITO film has the stable and fine oxide dielectric layer to make ITO film having a well thermal stabilization and a low resistivity.

According to the objectives of the present invention, a method of fabricating an indium tin oxide film (ITO film) with well thermal stabilization and low resistivity comprises the steps of:

a) Provide an oxide dielectric layer, which is an oxide film, on a substrate.

b) Provide an ion beam, which is generated by introducing oxygen to an ion source, to a surface of the oxide dielectric layer.

c) Provide an indium tin oxide film on the surface of the oxide dielectric layer.

### BRIEF DESCRIPTION OF THE DRAWINGS

FIG. 1 is a flow chart of a first preferred embodiment of the present invention;

FIG. 2(a) to FIG. 2(e) are sectional views according to the steps of the method of the first preferred embodiment of the present invention, and

FIG. 3 is a sectional view of a second preferred embodiment of the present invention.

### DETAILED DESCRIPTION OF THE INVENTION

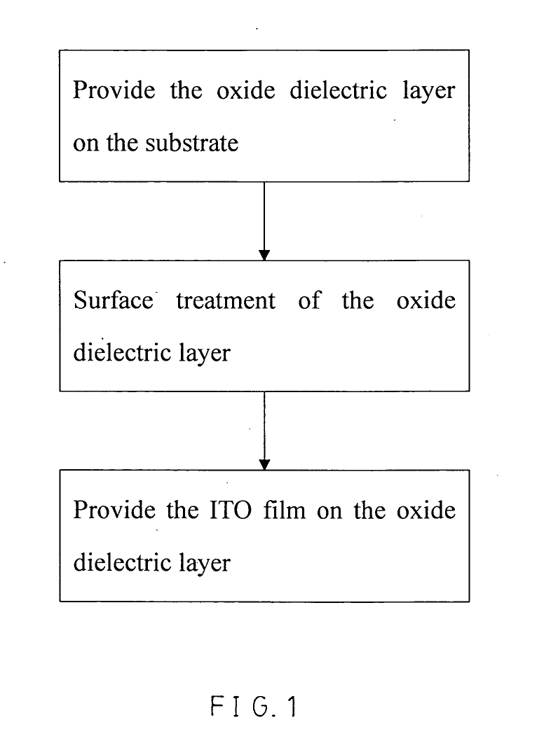

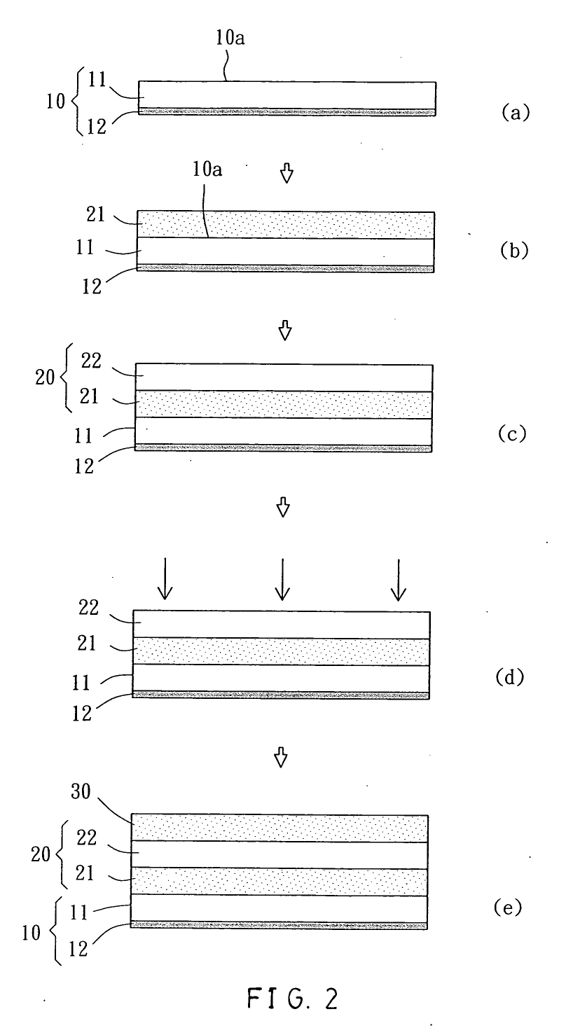

As shown in FIG. 1 and FIG. 2, a method of the first preferred embodiment of the present invention comprises the steps of:

a) Fabrication of an oxide dielectric layer.

Put a substrate 10 in a vacuum chamber of a sputtering machine (not shown). In the present preferred embodiment, the substrate 10 has a transparent plastic film 11 and a hard coating layer 12 on a side of the transparent plastic film 11, as shown in FIG. 2(a). The transparent plastic film 11 is made of polymer film, such as polyethylene terephthalate (PET). In practice, the transparent plastic film can be coated with two hard coating layers on opposite sides thereof.

Next, a titanium material and a silicon material are applied as a target in the sputtering process and oxygen is provided in the chamber to deposit a titanium dioxide film (TiO₂ film) 21 on a surface 10a, which is a side of the transparent plastic film 11 without the hard coating layer 12, of the substrate 10, as shown in FIG. 2(b), and to deposit a silicon dioxide film (SiO₂ film) 22 on the TiO₂ film 21, as shown in FIG. 2(c). The TiO₂ film 21 and the SiO₂ film 22 form an oxide dielectric layer 20. It is a well-known skill to fabricate the oxide dielectric layer in this step, so I would not describe the detail.

b) Surface treatment process of the oxide dielectric layer.

After Step a), the substrate 10 and the oxide dielectric layer 20 is treated by ion source(not shown), and then introduce oxygen to an ion source to generate an ion beam, the arrow in FIG. 2(d) shows the ion beam and emit a surface of the oxide dielectric layer 20. The ion beam fills empty portions of the oxide dielectric layer 20 to make the oxide dielectric layer 20 having a more stable and fine structure.

In the present preferred embodiment, in the process of generating ion beam, the ion source is a linear ion source, of course, it also can be a round ion source.

c) Fabrication of a transparent conductive film.

An Indium Tin Oxide film (ITO film) 30 is deposited on the surface of oxide dielectric layer 20, as shown in FIG. 2(e), and the ITO film 30 is the transparent conductive film. In the present preferred embodiment, the ITO film 30 is made by the sputtering process.

The present invention provides the oxide dielectric layer 20, which is designated to be anti-reflection, processed by oxygen ion beam to increase the stability and fin structure of the oxide dielectric layer 20. Therefore, while the panel is processed under a high-temperature environment, the oxygen in the oxide dielectric layer 20 will not diffuse to the ITO film 30. As a result, the thermal stabilization and the surface resistance of the ITO film 30 are kept stable to make the ITO film 30 having a high light transmission.

Table 1 is the values of surface resistance and resistivity of the ITO films, one of which the oxide dielectric layer thereon is processed by oxygen ion beam and the other is not. The Table 1 shows the surface resistance and the resistivity of the ITO films with the oxide dielectric layer processed by oxygen ion beam are significantly less.

TABLE 1

| | | With oxygen ion process | | Without oxygen ion process | |
|---|---|---|---|---|---|
| Before | Surface resistance | 392.5 | Ω/□ | 280.1 | Ω/□ |
| annealing | Resistivity | 8.635 × 10⁻⁴ | Ω/□ × cm | 6.1622 × 10⁻⁴ | Ω/□ × cm |
| After | Surface resistance | 500.8 | Ω/□ | 253.6 | Ω/□ |
| annealing | Resistivity | 1.10176 × 10⁻³ | Ω/□ × cm | 5.5792 × 10⁻⁴ | Ω/□ × cm |

In addition, the gas provided in the ion surface process could be the mixed gas of argon (Ar) and oxygen.

The oxide dielectric layer could have a plurality of the TiO₂ films and the SiO₂ films stacked to increase the efficiency of anti-reflection. Although, the resistivity is increased because of increasing of the stacked films of the oxide dielectric layer, the ion process will reduce the resistivity of ITO film.

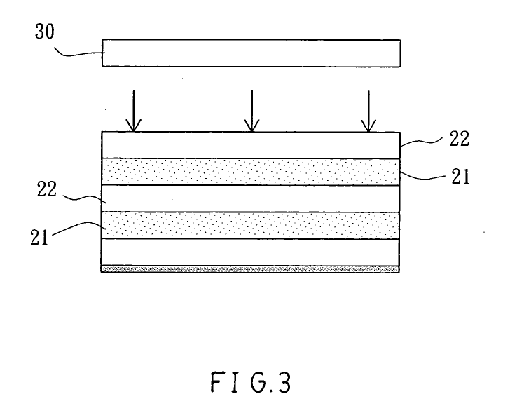

FIG. 3 shows the second preferred embodiment of the present invention, which is similar to the first preferred embodiment, except that it provides plural TiO₂ films 21 and SiO₂ films 22 stacked on a substrate 10, which the TiO₂ films 21 and the SiO₂ films 22 form an oxide dielectric layer 20. After the ion process (the arrow shows the ion beam), an ITO film 30 is deposited on the oxide dielectric layer 20.

Table 2 shows the surface resistances and the resistivity of the ITO films deposited on the oxide dielectric layer consisted of plural TiO₂ films and the SiO₂ films with and without oxygen ion beam process. The results show the surface resistances and the resistivity of the ITO films with oxygen ion beam process are significantly less.

TABLE 2

| | | With oxygen ion process | | Without oxygen ion process | |
|---|---|---|---|---|---|
| Before | Surface resistance | 415.3 | Ω/□ | 288.8 | Ω/□ |
| annealing | Resistivity | 9.1366 × 10⁻⁴ | Ω/□ × cm | 6.3536 × 10⁻⁴ | Ω/□ × cm |
| After | Surface resistance | 799.2 | Ω/□ | 303.7 | Ω/□ |
| annealing | Resistivity | 1.75824 × 10⁻³ | Ω/□ × cm | 6.6814 × 10⁻⁴ | Ω/□ × cm |

The scope of the present invention is not restricted in the preferred embodiments only. Any equivalent structure should be in the claim of the present invention.

What is claimed is:

1. A method, comprising the steps of:
a) providing an oxide dielectric layer, which is an oxide film, on a substrate;
b) providing an ion beam, which is generated by introducing oxygen to an ion source, to a surface of the oxide dielectric layer, and
c) providing an indium tin oxide film on the surface of the oxide dielectric layer.

2. The method as defined in claim 1, wherein the substrate has a plastic film and a hard coating layer on a side of the plastic film and the oxide dielectric layer is provided on a side of the plastic film without the hard coating layer.

3. The method as defined in claim 1, further comprises the step of providing a titanium dioxide film on the substrate, providing a silicon dioxide film on the titanium dioxide film in the step a).

4. The method as defined in claim 3, further comprising providing argon mixed with the oxygen to the ion source in the step b).

5. The method as defined in claim 1, wherein the oxide dielectric layer and the indium tin oxide film are made by sputtering processes.
